(19) United States
(12) Patent Application Publication
(10) Pub. No.: US 2009/0078307 A1
(43) Pub. Date: Mar. 26, 2009

(54) Three-Pole Two-Layer Photo-Rechargeable Battery

(75) Inventors: Hiroshi Segawa, Toyko (JP); Yosuke Saito, Toyko (JP); Satoshi Uchida, Tokyo (JP); Takaya Kubo, Tokyo (JP); Satoshi Fujita, Funabashi-shi (JP); Tadayuki Isaji, Funabashi-shi (JP)

Correspondence Address: OLIFF & BERRIDGE, PLC, P.O. BOX 320850, ALEXANDRIA, VA, 22320-4850, US

(73) Assignees: THE UNIVERSITY OF TOKYO, TOKYO (JP); NISSAN CHEMICAL INDUSTRIES, LTD., TOKYO (JP)

(21) Appl. No.: 12/076,913

(22) Filed: Mar. 25, 2008

(30) Foreign Application Priority Data
Sep. 26, 2007 (JP) 2007-249467

(51) Int. Cl. H01L 31/04

(52) U.S. Cl. 136/252

(57) ABSTRACT

A three-pole two-layer photo-rechargeable battery has a laminated two-layered structure that includes a solar battery cell, a storage cell, and a common electrode therebetween. The solar battery cell has a structure wherein a photo-electrode, which has a photo-sensitized dye and a semiconductor layer on a conductive substrate with optical transparency, counters via a first electrolytic solution a common electrode that has a catalyst layer on a conductive substrate. The storage cell has a structure wherein the common electrode, which has a first conductive polymer layer on a conductive substrate on a side opposite the catalyst layer, counters via a second electrolytic solution a storage cell counter electrode that has a second conductive polymer layer on a conductive substrate.

The disclosure of Japanese Patent Application No. 2007-249467 filed on Sep. 26, 2007 including the specification, drawings and abstract is incorporated herein by reference in its entirety.

### BACKGROUND OF THE INVENTION

1. Field of the Invention

The present invention relates to an energy storable dye-sensitized solar battery with excellent light energy storage performance. More specifically, the present invention relates to a three-pole two-layer photo-rechargeable battery formed from a solar battery cell and a storage cell.

2. Description of the Related Art

Research has been conducted in the past pertaining to dye-sensitized solar batteries. In 1991 the so-called Graetzel cell developed by Graetzel, et al. of Ecole Polytechnique de Lausanne in Switzerland gained attention for having high conversion efficiency despite its simple structure. However, solar batteries including the dye-sensitized solar battery have the disadvantage of being unable to generate power in dark locations since the power generation of solar batteries is dependent on light intensity, thus limiting their application as an individual battery.

Hence, a research group to which the inventors are affiliated focused on providing a dye-sensitized solar battery with a mechanism suited for inherent energy storage, on the basis of the fact that a conversion from light energy into chemical energy is included in the reaction process of the dye-sensitized solar battery. As a consequence, a three-pole energy storable dye-sensitized solar battery was developed that integrates a dye-sensitized solar battery and a storage battery, and includes a charge storage electrode in addition to a photo-electrode and a counter electrode (see Japanese Patent Application Publication No. JP-A-2004-288985).

Japanese Patent Application Publication No. JP-A-2004-288985 discloses an energy storable dye-sensitized solar battery that uses for the charge storage electrode a substance in which a polypyrrole film is deposited on an electrode plate formed from tin doped indium oxide (ITO). When this energy storable dye-sensitized solar battery is exposed to light, a portion of the electrons generated by excitation of the dye on the photo-electrode flow toward the charge storage electrode. Anion de-doping occurs on the polypyrrole film of the charge storage electrode, and charging is achieved in which light energy is converted and stored as chemical energy. The remaining electrons pass through a load between the counter electrode and the charge storage electrode, and flow toward the counter electrode.

Meanwhile, when the light is blocked, anion doping occurs on the polypyrrole film of the charge storage electrode, and the electrons flow through the load to the counter electrode for discharge. Note that a cation exchange membrane allows the coming and going of cations included in an electrolyte solution in two chambers separated by the cation exchange membrane. During charging cations flow in toward the charge storage electrode side, and during discharging cations flow out from the charge storage electrode side.

The group to which the inventors are affiliated also developed an energy storable dye-sensitized solar battery (Japanese Patent Application Publication No. JP-A-2006-172758) with better charging/discharging characteristics than the energy storable desensitized solar battery capable of charging/discharging described in Japanese Patent Application Publication No. JP-A-2004-288985.

The energy storable dye-sensitized solar battery according to Japanese Patent Application Publication No. JP-A-2006-172758 includes:

a cell part in which a photo-electrode having a dye-supporting semiconductor and a counter electrode facing the photo-electrode are arranged in a predetermined electrolyte solution; and

a battery part in which a charge storage electrode provided with a plurality of through holes having at least conductive polymers is arranged in a compartment partitioned from the electrolyte solution by a cation exchange membrane, with the battery part structured so as to enable the coming and going of a cation species of the electrolyte solution between the compartment and the electrolyte solution via the cation exchange membrane.

In the energy storable dye-sensitized solar battery described in Japanese Patent Application Publication No. JP-A-2006-172758, since the charge storage electrode has a plurality of through holes, the surface area is increased. Moreover, the surrounding solution freely passes through such through holes, thus increasing the contact efficiency between the conductive polymers and the solution. Accordingly, better charging/discharging characteristics can be achieved than when using a charge storage electrode without through holes.

However, the energy storable dye-sensitized solar batteries according to Japanese Patent Application Publication No. JP-A-2004-288995 and Japanese Patent Application Publication No. JP-A-2006-172758 perform hole storage through the oxidation-reduction of iodine in the electrolyte solution. Therefore, the maximum storage capacity is limited by the amount of iodine anions. In addition, the internal resistance of the charge storage electrode increases due to the presence of the cation exchange membrane. As a consequence, an adequate charging current cannot be obtained.

### SUMMARY OF THE INVENTION

It is an object of the present invention to provide an energy storable dye-sensitized solar battery capable of resolving the above-described problems, namely, to provide an energy storable dye-sensitized solar battery capable of improving a light energy storage capacity whose maximum storage capacity is not limited by an iodine anion amount in an electrolyte solution, and capable of obtaining an adequate charging current in a short time by reducing an internal resistance.

As a result of diligent research to solve the above problems, the inventors devised a way to improve a light energy storage capacity without increasing an amount of electrolyte solution, by using a three-pole two-layer structure formed from a solar battery cell and a storage cell, and by using a conductive polymer as a hole storage material. In addition, compared to a conductive polymer layer formed by electrolytic polymerization, forming the conductive polymer layer by coating a conductive polymer achieves a more uniform film and a larger surface area with a simpler process due to elimination of the polymerization process. As a consequence, a way to achieve a high light energy storage capacity was also discovered and such efforts culminated in completion of the present invention. Moreover, according to the present invention, a thin and lightweight three-pole two-layer photo-rechargeable battery can be achieved that does not require an ion exchange membrane such as described in Japanese Patent Application Publication No. JP-A-2006-172758, thus enabling a cell gap reduction as well as a reduction in the internal resistance of the charge storage electrode due to the absence of the ion exchange membrane, in addition to achieving a sufficient charging current in a shorter amount of time.

More specifically, the present invention pertains to the following.
(1) A three-pole two-layer photo-rechargeable battery has a laminated two-layered structure that includes a solar battery cell, a storage cell, and a common electrode therebetween, wherein

the solar battery cell has a structure wherein a photo-electrode, which has a photo-sensitized dye and a semiconductor layer on a conductive substrate with optical transparency, counters via a first electrolytic solution a common electrode that has a catalyst layer on a conductive substrate, and

the storage cell has a structure wherein the common electrode, which has a first conductive polymer layer on a conductive substrate on a side opposite the catalyst layer, counters via a second electrolytic solution a storage cell counter electrode that has a second conductive polymer layer on a conductive substrate.
(2) The three-pole two-layer photo-rechargeable battery according to (1), wherein the first conductive polymer layer is formed as a layer by coating a conductive polymer to form a film.
(3) The three-pole two-layer photo-rechargeable battery according to (2), wherein a method for coating the conductive polymer includes a spin coating method, a dip coating method, a bar coating method, a die casting method, and a doctor blade method.
(4) The three-pole two-layer photo-rechargeable battery according to (1), wherein the first conductive polymer layer includes polyaniline.
(5) The three-pole two-layer photo-rechargeable battery according to (2), wherein the first conductive polymer layer is formed as a layer by coating at least one of a solution, which includes polyaniline, and a dispersion liquid to form a film.
(6) The three-pole two-layer photo-rechargeable battery according to (5), wherein the solution that includes polyaniline is a polyaniline dispersion liquid.

According to the present invention, a thin three-pole two-layer photo-rechargeable battery can be provided that has excellent light energy storage performance and can achieve a charging current in a shorter amount of time, without tile volume of anions in an electrolyte solution limiting the maximum storage capacity. Furthermore, optimal compositions of electrolyte solution for both the solar battery cell and the storage cell structuring the three-pole two-layer photo-rechargeable battery according to the present invention can be obtained, and it is possible to provide a photo-rechargeable battery capable of achieving a higher photoelectric conversion characteristic and a better storage characteristic compared to a conventional type of integrated photo-rechargeable battery.

### BRIEF DESCRIPTION OF THE DRAWINGS

FIG. 1 is a schematic diagram showing a first example of an embodiment of a three-pole two-layer photo-rechargeable battery according to the present invention; and

FIG. 2 is a graph showing a discharging characteristic for energy storable dye-sensitized solar batteries manufactured in Examples 1 and 2 and Comparative Example 1.

### DETAILED DESCRIPTION OF THE PREFERRED EMBODIMENTS

A detailed description of the present invention is given below.

A three-pole two-layer photo-rechargeable battery according to the present invention has a two-layered structure formed from a solar battery cell and a storage cell divided by a common electrode.

The solar battery cell will be described first.

The solar battery cell has a structure wherein a photo-electrode, which has a photo-sensitized dye and a semiconductor layer on a conductive substrate with optical transparency, counters via a first electrolytic solution the common electrode that has a catalyst layer on a conductive substrate.

The photo-electrode has a photo-sensitized dye and a semiconductor layer on a conductive substrate with optical transparency.

The conductive substrate with optical transparency may be, for example, a transparent substrate formed from material capable of achieving efficient light transmittance and having suitable strength, such as glass or plastic, which has a transparent conductive film formed thereupon.

The transparent conductive film may be fluorine doped tin oxide (FTO), tin doped indium oxide (TTO), or a zinc oxide or the like doped with indium, aluminum or gallium, or may also be tin oxide, zinc oxide, niobium oxide, tungsten oxide, indium oxide, zirconium oxide, tantalum oxide or a combination thereof.

The transparent conductive film may be formed as a film on a substrate by a known method such as an electron beam method, a sputtering method, a resistance heating deposition method, an ion plating method, a chemical reaction method (such as the sol-gel process), a spray method, a dip method, a thermal CVD method, or a plasma CVD method.

The semiconductor layer may be, for example, a porous body with a large semiconductor surface area such as titanium oxide, niobium oxide, zinc oxide, zirconium oxide, tantalum oxide, tin oxide, tungsten oxide, indium oxide, or gallium arsenide. However, the semiconductor layer is preferably a porous body made of titanium oxide.

The photo-sensitized dye is not particularly limited, provided that it absorbs light in at least one region among the ultraviolet light, visible light, and infrared light regions, and electrons are implanted on a semiconductor forming a porous semiconductor layer. For example, the photo-sensitized dye may be a ruthenium-based dye, a porphyrin-based dye, a phthalocyanine-based dye, a rhodamine-based dye, a xanthein-based dye, a chlorophyl-based dye, a triphenyl methane-based dye, an acridine-based dye, a coumarin-based dye, an oxazine-based dye, an indigo-based dye, a cyanine-based dye, a merocyanine-based dye, a rhodacyanine-based dye, an eosin-based dye, or a mercurochrome-based dye. However, the photo-sensitized dye is preferably a ruthenium bipyridyl complex such as ruthenium-tris(2,2′-bispyridyl-4,4′-dicarboxylate), ruthenium-cis-dithiocyano-bis(2,2′-bipyridyl-4,4′-dicarboxylate), ruthenium-cis-diaqua-bis(2,2′-bipyridyl-4,4′-dicarboxylate), ruthenium-cyano-tris(2,2′-bipyridyl-4,4′-dicarboxylate), cis-(SCN)-bis(2,2′-bipyridyl-4,4′-dicarboxylate, or ruthenium.

The photo-sensitized dye is chosen so as to have a higher excitation level than an energy level on the lower end of the conduction band of the semiconductor forming the semiconductor layer.

The photo-sensitized dye normally adsorbed to the semiconductor layer.

The method for adsorbing the photo-sensitized dye to the semiconductor layer may include coating a solution in which the photo-sensitized dye has been dissolved in a solvent on the semiconductor layer by means of spray coating, spin coating or the like, after which formation is achieved by a drying method. In such case, the substrate may be heated to a suitable temperature. In addition, a method may be used in which the semiconductor layer is immersed in a solution to enable adsorption. The immersion period is not particularly limited, provided that the photo-sensitized dye can be sufficiently adsorbed. The immersion period is preferably 0.5 to 30 hrs, and more preferably 2 to 20 hrs. Also, the solvent and the substrate may be heated as necessary upon immersion. The concentration of the photo-sensitized dye for the solution is preferably about 0.1 to 1000 mM/L, and more preferably about 1 to 500 mM/L.

The solvent used is not particularly limited, provided that it dissolves the photo-sensitized dye without dissolving the semiconductor layer. Solvents that may be used include: an alcohol such as methanol, ethanol, 1-propanol, 2-propanol, 1-butanol, 2-butanol, or t-butanol; a nitrile-based solvent such as acetonitrile, propionitrile, methoxypropionitrile, or glutaronitrile; benzene; toluene; o-xylene; m-xylene; p-xylene; pentane; heptane; hexane; cyclohexane; heptane; acetone; methyl ethyl ketone; diethyl ketone; 2-butanone; diethyl ether; tetrahydrofuran; ethylene carbonate; propylene carbonate; nitromethane; dimethyl formamide; dimethyl sulfoxide; hexamethyl phosphoanide; dimethoxyethane; γ-butyrolactone; γ-valerolactone; sulfolane; dimethoxyethane; adiponitrile; methoxyacetonitrile; dimethyl acetoamide; methyl pyrrolidinone; dimethyl sulfoxide; dioxolan; sulfolane; trimethyl phosphate; triethyl phosphate; tripropyl phosphate; ethyl dimethyl phosphate; tributyl phosphate; tripentyl phosphate; trihexyl phosphate; triheptyl phosphate; trioctyl phosphate; trinonyl phosphate; tridecyl phosphate; tis(trifluoromethyl) phosphate; tris(pentafluoroethyl) phosphate; triphenyl polyethylene glycol phosphate; or polyethylene glycol.

The photo-electrode has a structure wherein the semiconductor layer to which the photo-sensitized dye is adsorbed is formed on the conductive substrate.

The common electrode has a structure wherein a face of the conductive substrate is formed with a catalyst layer, and another face on an opposing side is formed with a conductive polymer layer.

The conductive substrate should be a conductive substrate with corrosion resistance to ions present in the electrolyte used. A non-conductive substrate formed with a conductive film on both sides thereof may also be used. Furthermore, the material, thickness, dimension, shape and the like may be selected as appropriate depending on the purpose. Conceivable conductive substrates include metals such as stainless steel, titanium, tungsten, molybdenum, and platinum. Conceivable non-conductive substrates include, for example, colorless or colored glass or the like, and colorless or colored transparent resin or the like. Specific examples of such resins include: a polyester such as polyethylene terephthalate, polyamide, polysulfone, polyether sulfone, polyether ether ketone, polyphenylene sulfide, polycarbonate, polyimide, polymethyl methacrylate, polystyrene, cellulose triacetate, and polymethyl pentane. Note that the substrate according to the present invention has a smooth surface at ambient temperature, and the surface thereof may be flat or curved and may also deform due to stress.

The conductive film formed on the nonconductive substrate may be, for example, a conductive coating formed from a thin metallic film such as titanium, tungsten or molybdenum, or a metal oxide.

The metal oxide is preferably indium tin oxide (ITO (IN₂O₃:Sn)), fluorine doped tin oxide (FTO (SnO₂:F)), aluminum doped zinc oxide (AZO (ZnO:Al)) or the like wherein a metal oxide such as indium, tin or zinc is doped with a minute amount of another metal element.

The conductive coating normally has a thickness of 10 nm to 2 μm, and more preferably 100 nm to 1 μm. The sheet resistance is normally 0.5 to 100 Ω/□, and more preferably 2 to 50 Ω/□. Such conductive coatings can be manufactured on the substrate using a known method such as a vacuum deposition method, an ion plating method, a CVD method, an electron beam vacuum deposition method, a sputtering method, and a spraying method.

The catalyst layer formed on the conductive substrate may be, for example, a platinum electrode, a gold electrode, a silver electrode, a carbon electrode, or a palladium electrode. However, a platinum electrode is preferable for its superior catalyst effect. In addition, it is not necessary to further form a catalyst layer on the conductive substrate in cases where the conductive substrate is structured by the above metals or a thin film of the above metals is formed on the substrate.

The first electrolytic solution may use a solution that includes a redox-based reductant (e.g. I⁻) and an oxidant (e.g. I₃⁻). The photo-sensitized dye excited by exposure to light attains an oxidation state in which electrons are implanted on the conduction band of the semiconductor that forms the semiconductor layer. However, the reductant in the first electrolytic solution changes into an oxidant through the provision of electrons to the oxidized photo-sensitized dye. The oxidant changes back into a reductant by the acceptance of electrons from the common electrode. Note that at such time, the catalyst layer of the conductive substrate demonstrates a catalyst effect that changes the oxidant back into a reductant. Such a first electrolytic solution may be, for example, a solution that includes iodide ions and iodine, a solution that includes quinone and hydroquinone, or a solution that includes bromide ions and bromine. The solvent for such solutions may be a solvent that dissolves these substances, such as acetonitrile, ethylene carbonate, propylene carbonate, methanol, ethanol, and butanol.

In addition to the above liquids, the first electrolytic solution may also contain a polymer solid electrolyte (e.g. an ion conductive film or the like). A particularly preferable polymer solid electrolyte has a polymer matrix that contains at least a substance demonstrating a reversible electrochemical oxidation-reduction characteristic. Also conceivable is a substance that further contains a desired plasticizer. In addition to the above, other arbitrary components may also be added as desired, including an electrolyte and ambient temperature molten salt.

A material that can be used as the polymer matrix is not particularly limited, provided that a solid state or a gel state can be formed with the polymer matrix alone or by the addition of a plasticizer, the addition of an electrolyte, or by the addition of a plasticizer and an electrolyte. The material may also be a so-called polymer compound in general use.

Conceivable polymer compounds demonstrating the characteristic of the above polymer matrix include polymer compounds that can be obtained by polymerizing or copolymerizing a monomer such as hexaphloropropylene, tetraphloroethylene, triphloroethylene, ethylene, propylene, acrylonitrile, vinylidene chloride, acrylic acid, methacrylic acid, methyl acrylate, ethyl acrylate, methyl methacrylate, styrene, or vinylidene fluoride. In addition, the polymer compounds may be used alone or in combination. However, a polyvinylidene fluoride-based polymer compound is preferable.

The storage cell will be described next.

The storage cell has a structure wherein the common electrode, which has a first conductive polymer layer on a conductive substrate on a side opposite the catalyst layer, counters via a second electrolytic solution a storage cell counter electrode that has a second conductive polymer layer on a conductive substrate.

The first conductive polymer layer can be formed by electrolytic copolymerization of a monomer corresponding to the conductive polymer on the conductive substrate of the common electrode, and can also be formed by coating a liquid containing conductive polymers on the conductive substrate of the common electrode for film formation.

The conductive polymer layer formed by coating a liquid containing conductive polymers for film formation can achieve a more uniform conductive polymer film compared to the conductive polymer layer formed by the electrolytic polymerization method, and is preferable for its high light energy storage performance.

Conceivable conductive polymers for structuring the first conductive polymer layer include one or more species selected from a group consisting of polypyrrole, polyaniline, polythiophene, polyacetylene, polyphenylene, polyphenylene vinylene, polyacene. polyvinyl carbazole, polyviologen, polyporphyrin, polyphthalocyanine, polyferrocene, polyamine, and polymer derivatives therefrom, as well as a carbon nanotube, fullerene, polymers containing quinoline. However, polyaniline is preferable.

For formation of the first conductive polymer layer using the electrolytic polymerization method, electrochemical oxidation polymerization may be performed, for example, in an electrolyte solution containing a monomer (such as pyrrole, aniline, thiophene, and acetylene) corresponding to the conductive polymer.

For formation of the first conductive polymer layer through coating a liquid containing conductive polymers to form a film, the liquid containing conductive polymers is coated on the conductive substrate and the conductive polymer layer is formed by performing heating, drying, or the like as necessary.

Conceivable dispersion liquids containing conductive polymers include dispersion liquids described in International Publication Pamphlet No. 2006/087969, International Publication Pamphlet No. 2007/052852, Japanese Patent Application Publication No. JP-A-H07-90060, the Japanese translation of PCT International Application No. H02-500918, and the Japanese translation of PCT International Application No. 2001-518859.

An average particle size of the conductive polymer used in the liquid containing conductive polymers (according to a dynamic light scattering method) is preferably 500 nm or less.

A normal solvent is used for the above liquid. The solvent used is not particularly limited, and conceivable solvents include water, an alcohol solvent such as methanol, ethanol and n-butanol, ketone solvents such as acetone, methyl ethyl ketone and diethyl ketones and aromatic hydrocarbon solvents such as toluene and xylene.

In addition, a binder, a dopant, and the like may also be added to the above liquid as necessary.

Conceivable dopants include: sulfonic acids such as polystyrene sulfonate, paratoluene sulfonate, methane sulfonate, trifluoromethane sulfonate, anthraquinone sulfonate, benzene sulfonate, naphthalene sulfonate, sulfosalicylic acid, dodecylbenzene sulfonate and allyl sulfonate, carboxylic acids such as acetic acid, halogens such as perchloric acid, chlorine and bromine, as well as Lewis acid, and protonic acid.

Conceivable binders include: polyvinyl chloride, polycarbonate, polystyrene, polymethyl methacrylate, polyester, polysulfone, polyphenylene oxide, polybutadiene, poly(N-vinyl carbazole), hydrocarbon resin, ketone resin, phenoxy resin, polyamide, ethyl cellulose, vinyl acetate, ABS resin, polyurethane resin, melamine resin, unsaturated polyester resin, alkyd resin, epoxy resin, and silicon resin.

Furthermore, resins such as a thickener, a dispersion stabilizer, and an ink binder can also be added to the above liquid as necessary.

A solid content of the prepared liquid containing conductive polymers is preferably in the range of 0.3 to 10% by mass.

The liquid containing conductive polymers is preferably a conductive polymer dispersion liquid

The first conductive polymer layer can be formed by coating the liquid containing conductive polymers on the conductive substrate, and performing drying through heating or the like as necessary.

The method for coating the liquid containing conductive polymers on the conductive substrate is not particularly limited, and coating is preferably performed, for example, with a screen printer, a gravure printer, a flexographic press, an ink jet printer, an offset printer or the like, and by printing or coating using a spin coating method, a dip coating method, a bar coating method, a die casting method, or a doctor blade method. However, coating using the spin coating method, the dip coating method, the bar coating method, the die casting method or the doctor blade method is preferable.

A thickness of the first conductive polymer layer formed is not particularly limited, but is preferably 0.5 μm or above, and more preferably 1 μm or above. Alternatively, the thickness is preferably 50 μm or below, and more preferably 30 μm or below.

A surface resistance after formation of the first conductive polymer layer is preferably from about 1 to 500 Ω/□, and a conductivity thereof is preferably from about 10 to 500 S/cm.

The storage cell counter electrode has a structure wherein the second conductive polymer layer is formed on a conductive substrate.

The conductive substrate should be a conductive substrate with corrosion resistance to ions present in the electrolyte used. A non-conductive substrate formed with a conductive film may also be used. Furthermore, the material, thickness, dimension, shape and the like may be selected as appropriate depending on the purpose. Conceivable conductive substrates include metals such as stainless steel, titanium, tungsten, molybdenum, and platinum. Conceivable non-conductive substrates include, for example, colorless or colored glass or the like, and colorless or colored transparent resin or the like. Specific examples of such resins include: a polyester such as polyethylene terephthalate, polyamide, polysulfone, polyether sulfone, polyether ether ketone, polyphenylene sulfide, polycarbonate, polyimide, polymethyl methacrylate, polystyrene, cellulose triacetate, and polymethyl pentane. Note that the substrate according to the present invention has a smooth surface at ambient temperature, and the surface thereof may be flat or curved and may also deform due to stress.

The conductive film formed on the non-conductive substrate may be, for example, a conductive coating formed from a thin metallic film such as titanium, tungsten or molybdenum, or a metal oxide.

The metal oxide is preferably indium tin oxide (ITO (In₂O₃:Sn)), fluorine doped tin oxide (FTO (SnO₂:F)), aluminum doped zinc oxide (AZO (ZnO:Al)) or the like wherein a metal oxide such as indium, tin or zinc is doped with a minute amount of another metal element.

The conductive coating normally has a thickness of 10 nm to 2 μm, and more preferably 100 nm to 1 μm. The sheet resistance is normally 0.5 to 100 Ω/□, and more preferably 2 to 50 Ω/□. Such conductive coatings can be manufactured on the substrate using a known method such as a vacuum deposition method, an ion plating method, a CVD method, an electron beam vacuum deposition method, a sputtering method, and a spraying method.

The second conductive polymer layer can be formed by electrolytic polymerization of a monomer corresponding to the conductive polymer on the conductive substrate, and can also be formed by coating a liquid containing conductive polymers on the conductive substrate for film formation.

Conceivable conductive polymers for structuring the second conductive polymer layer include one or more species selected from a group consisting of polypyrrole, polyaniline, polythiophene, polyacetylene, polyphenylene, polyphenylene vinylene, polyacene, polyvinyl carbazole, polyviologen, polyporphyrin, polyphthalocyanine, polyferrocene, polyamine, and polymer derivatives therefrom, as well as a carbon nanotube, fullerene, polymers containing quinoline. However, polyaniline is preferable.

For formation of the second conductive polymer layer using the electrolytic polymerization method, electrochemical oxidation polymerization may be performed, for example, in an electrolyte solution containing a monomer (such as pyrrole, aniline, and thiophene) corresponding to the conductive polymer.

For formation of the second conductive polymer layer through coating a liquid containing conductive polymers to form a film, the liquid containing conductive polymers is coated on the conductive substrate and the conductive polymer layer is formed by performing heating, drying, or the like as necessary.

An average particle size of the conductive polymer used in the liquid containing conductive polymers (according to a dynamic light scattering method) is preferably 500 nm or less.

A normal solvent is used for the above liquid. The solvent used is not particularly limited, and conceivable solvents include water, an alcohol solvent such as methanol, ethanol and n-butanol, ketone solvents such as acetone, methyl ethyl ketone and diethyl ketone, and aromatic hydrocarbon solvents such as toluene and xylene.

In addition, a binder, a dopant, and the like may also be added to the above liquid as necessary.

Conceivable dopants include: sulfonic acids such as polystyrene sulfonate, paratoluene sulfonate, methane sulfonate, trifluoromethane sulfonate, anthraquinone sulfonate, benzene sulfonate, naphthalene sulfonate, sulfosalicylic acid, dodecylbenzene sulfonate and allyl sulfonate, carboxylic acids such as acetic acid, halogens such as perchloric acid, chlorine and bromine, as well as Lewis acid, and protonic acid.

Conceivable binders include: polyvinyl chloride, polycarbonate, polystyrene, polymethyl methacrylate, polyester, polysulfone, polyphenylene oxide, polybutadiene, poly(N-vinyl carbazole), hydrocarbon resin, ketone resin, phenoxy resin, polyamide, ethyl cellulose, vinyl acetate, ABS resin, polyurethane resin, melamine resin, unsaturated polyester resin, alkyd resin, epoxy resin, and silicon resin.

Furthermore, resins such as a thickener, a dispersion stabilizer, and an ink binder can also be added to the above liquid as necessary.

A solid content of the prepared liquid containing conductive polymers is preferably in the range of 0.3 to 10% by mass.

The liquid containing conductive polymers is preferably a conductive polymer dispersion liquid.

The second conductive polymer layer can be formed by coating the liquid containing conductive polymers on the conductive substrate, and performing drying through heating or the like as necessary.

The method for coating the liquid containing conductive polymers on the conductive substrate is not particularly limited, and coating is preferably performed, for example, with a screen printer, a gravure printer, a flexographic press, an ink jet printer, an offset printer or the like, and by printing or coating using a spin coating method, a dip coating method, a bar coating method, a die casting method, or a doctor blade method. However, coating using the spin coating method, the dip coating method, the die casting method or the doctor blade method is preferable.

A thickness of the second conductive polymer layer formed is not particularly limited, but is preferably 0.5 μm or above, and more preferably 1 μm or above. Alternatively, the thickness is preferably 50 μm or below, and more preferably 30 μm or below.

A surface resistance after formation of the second conductive polymer layer is preferably from about 1 to 500 Ω/□, and a conductivity thereof is preferably from about 10 to 500 S/cm.

The second electrolytic solution is a liquid that includes dc-doped or doped anions in the first conductive polymer layer and the second conductive polymer layer at charging/discharging. The anions may be ClO₄⁻, BF₄⁻, NO₃⁻, HSO₄⁻, PF₆⁻, and CF₃SO₃⁻ and the like, and are preferably ClO₄⁻ and BF₄⁻.

In addition to the above liquids, the second electrolytic solution also contains a polymer solid electrolyte (e.g. an ion conductive film or the like). A particularly preferable polymer solid electrolyte has a polymer matrix that contains at least the anions mentioned above. Also conceivable is a substance that further contains a desired plasticizer. In addition to the above, other arbitrary components may also be added as desired, including another electrolyte and ambient temperature molten salt.

A material that can be used as the polymer matrix is not particularly limited, provided that a solid state or a gel state can be formed with the polymer matrix atone or by the addition of a plasticizer, the addition of an electrolyte, or by the addition of a plasticizer and an electrolyte. The material may also be a so-called polymer compound in general use.

Conceivable polymer compounds demonstrating the characteristic of the above polymer matrix include polymer compounds that can be obtained by polymerizing or copolymerizing a monomer such as hexaphloropropylene, tetraphloroethylene, triphloroethylene, ethylene, propylene, acrylonitrile, vinylidene chloride, acrylic acid, methacrylic acid, methyl acrylate, ethyl acrylate, methyl methacrylate, styrene, or vinylidene fluoride. In addition, the polymer compounds may be used alone or in combination. However, a polyvinylidene fluoride-based polymer compound is preferable.

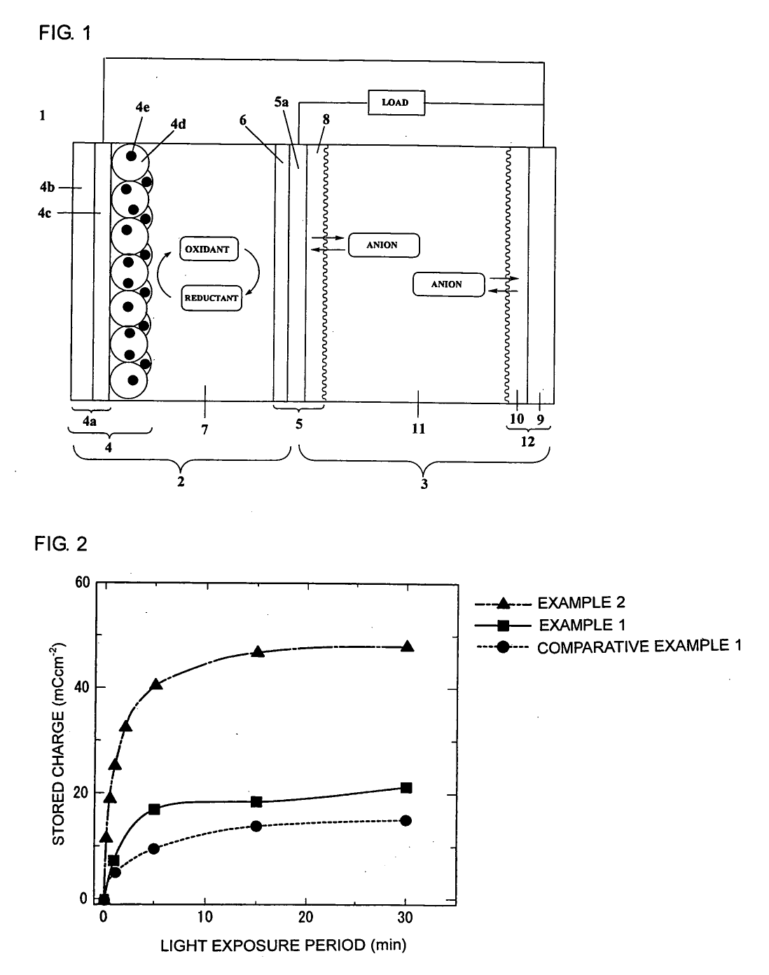

An example of an embodiment of the three-pole two-layer photo-rechargeable battery according to the present invention will be described next using FIG. 1. A three-pole two-layer photo-rechargeable battery 1 according to the present invention has, for example, a two-layer structure wherein a solar battery cell 2 and a storage cell 3 are divided by a common electrode 5 and laminated. The solar battery cell 2 has a structure wherein a photo-electrode 4, which has a semiconductor layer 4d and a photo-sensitized dye 4e on a conductive substrate 4a with optical transparency (wherein the conductive substrate 4a is formed from a transparent substrate 4b and a transparent conductive film 4c formed on the substrate), counters the common electrode 5, which has a catalyst layer 6 on a conductive substrate 5a, via a first electrolytic solution 7. The storage cell 3 has a structure wherein the common electrode 5, which has a first conductive polymer layer 8 on a conductive substrate 5a that is on a side opposite the catalyst layer 6, counters a storage cell counter electrode 12, which has a second conductive polymer layer 10 on a conductive substrate 9, via a second electrolytic solution 11.

A charging mechanism of the three-pole two-layer photo-rechargeable battery according to the present invention will be described using FIG 1. Light irradiating the photo-electrode 4 excites the photo-sensitized dye 4e. Electrons from the excited photo-sensitized dye 4e are then implanted on the conduction band of the semiconductor forming the semiconductor layer 4d. In the present embodiment, the excitation level of the photo-sensitized dye 4e is higher than the energy level on the lower end of the conduction band of the semiconductor forming the semiconductor layer 4e, thus generating such electron movement. Electrons implanted on the semiconductor forming the semiconductor layer 4d flow from the transparent conductive film 4c of the photo-electrode 4 to the conductive substrate 9 of the storage cell counter electrode 12. When this happens, the second conductive polymer layer 10 on the conductive substrate 9 accepts the electrons, whereby de-doping occurs and releases anions in the second electrolytic solution 11. The first conductive polymer layer 8 is doped with the released anions, and as a consequence, hole storage is performed in the first conductive polymer layer 8. Meanwhile, the oxidized photo-sensitized dye 43 that provided electrons to the semiconductor forming the semiconductor layer 4d receives electrons from the redox-based reductant in the first electrolytic solution and changes back to a neutral state. And the reductant that gave up the electrons changes back to an oxidant. In this manner, electrons generated by the photo-electrode 4 due to light exposure are accumulated in the second conductive polymer layer 10 on the conductive substrate 9 of the storage cell counter electrode 12.

Next, a discharging mechanism of the three-pole two-layer photo-rechargeable battery according to the present invention will be described using FIG. 1. Anion doping occurs in the second conductive polymer layer 10 on the conductive substrate 9 of the storage cell counter electrode 12, and electrons flow from the conductive substrate 9 of the storage cell counter electrode 12 to the conductive substrate 5a of the common electrode 5 via a load. In this manner, the electrons accumulated in the second conductive polymer layer 10 on the conductive substrate 9 of the storage cell counter electrode 12 flow to the common electrode 5 via the load and are discharged.

### EXAMPLES

Examples are given below to concretely describe the present invention. However, the present invention is not limited by such examples in any manner.

### Production Example 1

### Manufacture of Photo-Electrode

A TiO₂ paste (Ti Nanoxide D, Solaronix) was coated on an FTO glass substrate (2 cm×2.5 cm×1 mm) using the doctor blade method. Following coating, the past was baked at 550° C. for 30 min in an electric furnace and then cooled at room temperature. After immersion for 20 hrs in a dye solution, a photo-electrode was manufactured. The dye solution used dissolved 0.3 mM of N719 (Peccell Technologies) in a mixed solvent (1:1) of acetonitrile (AN) and t-butyl alcohol.

### Production Example 2

### Manufacture of Common Electrode on Which First Conductive Polymer Layer (Polyaniline Layer) is Formed by Electrolytic Polymerization

A platinum film with a thickness of 30 nm was formed on a surface of a titanium substrate (thickness: 1 mm) using the sputtering method. On a surface of an opposite side thereof, polyaniline was subjected to electrolytic polymerization according to the following procedure. For the polymerization solution, an aqueous solution of 0.5 M aniline and 1 M HClO₄ was used. For the polymerization method, a controlled potential electrolytic polymerization method at +0.8 V (vs. SCE) was used. The electrolytic polymerization volume was 1 Ccm⁻². In such case, the thickness of the polyaniline layer obtained was 20 μm.

### Production Example 3

### Manufacture of Common Electrode on Which First Conductive Polymer Layer (Polyaniline Layer) is Formed by Spin Coating

A platinum film with a thickness of 30 nm was formed on a surface of a titanium substrate (thickness: 1 mm) using the sputtering method. On a surface of an opposite side thereof, a polyaniline dispersion liquid (NX-B001X, Nissan Chemical Industries) was spin-coated. The spin-coated film obtained was a relatively homogeneous film with a thickness of approximately 20 μm.

### Production Example 4

### Manufacture of Storage Cell Counter Electrode on Which Second Conductive Polymer Layer (Polypyrrole Layer) is Formed

For the electrolyte solution in the electrolytic polymerization, a PC solution of 0.1 M pyrrole (Py) and 0.1 M LiClO₄ was used. A tin doped indium oxide (ITO) substrate was used as the substrate for electrolytic polymerization of pyrrole. For the counter electrode, a platinum plate electrode (1 cm×1 cm) was used. A saturated calomel electrode (SCE) (manufactured by BAS) was used as a reference electrode. Regarding electrolytic polymerization, synthesis was achieved through electrolytic polymerization at a constant current (0.5 mAcm⁻²) using a potentiostat (HA-151, Hokuto Denko). The polymerization electric charge of PPy was 5 mCcm⁻². Following polymerization, the electrodes were cleaned with acetonitrile. The film thickness of the polypyrrole layer obtained was approximately 2.5 μm.

### Example 1

### Manufacture of Three-Pole Two-Layer Photo-Rechargeable Battery

The photo-electrode manufactured in Production Example I and a common electrode substrate formed with the polyaniline layer manufactured in Production Example 2 are disposed with a gap of approximately 20 μm. A UV curable resin is coated around the substrate and hardened by exposure to an Xe lamp for 60 sec. Furthermore, using double-sided tape (manufactured by 3M) as a spacer, the storage cell counter electrode formed with the polypyrrole layer manufactured in Production Example 4 is disposed with a gap of 0.64 mm. For the electrolyte solution of the solar battery cell, 0.1 M LiI, 0.05 M I₂, 0.6 M DMPII, and 0.5 M TBP (DMPII: 2,3-dimethyl-1-propyl imidazolium iodide, TBP: 4-tert-butyl pyridine) were used, while 0.5 M LiClO₄/propylene carbonate was used for the electrolyte solution of the storage cell. The electrolyte solution is injected by syringe from injection holes at two location made in the photo-electrode and the storage cell counter electrode, which are then sealed by light-cured resin to form a three-pole two-layer photo-rechargeable battery according to Example 1.

### Example 2

A three-pole two-layer photo-rechargeable battery according to Example 2 was manufactured by performing the same operations as in Example 1, with the exception of using the common electrode substrate formed with the polyaniline layer manufactured in Production Example 3 instead.

### Comparative Example 1

An integrated energy storable dye-sensitized solar battery was manufactured according to a manufacturing method described in Example 1 of Japanese Patent Application Publication No. JP-A-2006-172758, which is specified below.

The following are stacked in sequence and interspersed with cocks: a photo-electrode, a counter electrode accommodated in a rectangular window that is substantially centered on a first silicon rubber that is generally the same size as the photo-electrode, a cation exchange membrane generally the same size as the first silicon rubber, a second silicon rubber having a centered rectangular window, and a charge storage electrode generally the same size as the rectangular window of the second silicon rubber. A first electrolyte solution is injected into the rectangular window of the first silicon rubber, and a second electrolyte solution is injected into the rectangular window of the second silicon rubber, thus creating an integrated energy storable dye-sensitized solar battery.

Note that the photo-electrode was manufactured by heating a porous titanium oxide electrode (manufactured by Nisinoda Electronics) on a hot plate for 30 min at 450° C., which is followed by cooling until the electrode reaches normal temperature. This was then placed in an ethanol solution containing 0.3 mM of N3 dye (manufactured by Kisco) and left to rest for 1 day, after which the electrode was removed and dried. The counter electrode was manufactured using a platinum 150-mesh electrode with a mesh size of 1 cm (vertical)×1 cm (lateral). The charge storage electrode was manufactured by separating a polypyrrole film (whose thickness measured several μm) from the top of a stainless steel grid member. More specifically, constant-current electrolytic oxidation polymerization was performed at an electric charge of 200 mCmc⁻² and a current density of +500 μAcm⁻² on a stainless steel grid member, which is provided with a platinum counter electrode, a reference electrode using a saturated calomel electrode and a working electrode using a stainless steel grid member (1 cm (vertical)×1 cm (lateral); wire diameter: 0.1 mm; 100 mesh), and which is placed in a propylene carbonate solution of 0.1 M pyrrole and 0.1 M lithium perchlorate. A first silicon rubber 40 had a thickness of 3 mm, and a rectangular opening formed so as to achieve a 1 cm² effective electrode surface area. The second silicon rubber was identical to the first silicon rubber. The first electrolyte solution was a propylene carbonate solution containing 0.5 M lithium iodide and 0.05 M iodine, while the second electrolyte solution was a propylene carbonate solution containing 0.5 M lithium perchlorate.

### Test Example 1

An evaluation was made of the discharging characteristic of the energy storable dye-sensitized solar batteries manufactured in Examples 1 and 2 and Comparative Example 1.

For a light source, a 500 W Xe lamp (Ushio) was used with an AM filter. A laser power meter (Ophir Optronics) was used to control the light intensity on the cell surface to 100 mWcm⁻² and adjust the position of the cell. During solar charging (during light exposure), charging was performed by short-circuiting the photo electrode and the storage cell counter electrode. During discharge, a space between the photo electrode and the storage cell counter electrode is opened so that discharging is performed by the counter electrode and the storage cell counter electrode. Discharging is carried out through constant current discharge (30 μAcm⁻²).

FIG. 2 shows the discharging characteristic of the energy storable dye-sensitized solar batteries manufactured in Examples 1 and 2 and Comparative Example 1. The batteries of Examples 1 and 2 of the present invention are three-pole two-layer energy storable dye-sensitized solar batteries, and clearly show a higher discharging capacity and a higher charging speed than the battery of Comparative Example 1, which is an integrated energy storable dye-sensitized solar battery. In addition, the battery of Example 2, which used polyaniline created by spin coating, achieved more than double the discharging capacity of the battery of Example 1, which used polyaniline created by electrolytic polymerization.

What is claimed is:

1. A three-pole two-layer photo-rechargeable battery comprising a laminated two-layered structure that includes a solar battery cell, a storage cell, and a common electrode therebetween, wherein
the solar battery cell has a structure wherein a photo-electrode, which has a photo-sensitized dye and a semiconductor layer on a conductive substrate with optical transparency, counters via a first electrolytic solution the common electrode that has a catalyst layer on a conductive substrate, and
the storage cell has a structure wherein the common electrode, which has a first conductive polymer layer on a conductive substrate on a side opposite the catalyst layer, counters via a second electrolytic solution a storage cell counter electrode that has a second conductive polymer layer on a conductive substrate.

2. The three-pole two-layer photo-rechargeable battery according to claim 1, wherein the first conductive polymer layer is formed as a layer by coating a conductive polymer to form a film.

3. The three-pole two-layer photo-rechargeable battery according to claim 2, wherein a method for coating the conductive polymer includes a spin coating method, a dip coating method, a bar coating method, a die casting method, and a doctor blade method.

4. The three-pole two-layer photo-rechargeable battery according to claim 1, wherein the first conductive polymer layer includes polyaniline.

5. The three-pole two-layer photo-rechargeable battery according to claim 2, wherein the first conductive polymer layer is formed as a layer by coating a solution or a dispersion liquid that includes polyaniline, to form a film.

6. The three-pole two-layer photo-rechargeable battery according to claim 5, wherein the solution or the dispersion liquid that includes polyaniline is a polyaniline dispersion liquid.
